(19) United States
(12) Patent Application Publication
(10) Pub. No.: US 2026/0177633 A1
(43) Pub. Date: Jun. 25, 2026

(54) METHOD AND SYSTEM FOR MISSION-DEFINED FITNESS OF AN ENERGY STORAGE SYSTEM

(71) Applicant: ELECTRA VEHICLES, INC., Boston, MA (US)

(72) Inventors: Noah Johnson, Boston, MA (US); Thomas Couture, Boston, MA (US); Freeman Rufus, Jr., Boston, MA (US); David Aaron Rivkin, Boston, MA (US); Fabrizio Martini, Boston, MA (US)

(73) Assignee: ELECTRA VEHICLES, INC., Boston, MA (US)

(21) Appl. No.: 19/127,637

(22) PCT Filed: Nov. 7, 2023
(86) PCT No.: PCT/US2023/036956

§ 371 Date: May 6, 2025

Related U.S. Application Data
(60) Provisional application No. 63/423,154, filed on Nov. 7, 2022.

(51) Int. Cl. G01R 31/392; H01M 10/48

(52) U.S. Cl. CPC G01R 31/392; H01M 10/48; H01M 10/482

(57) ABSTRACT

Methods and apparatus for determining a fitness of a battery for a candidate mission are provided. The method includes receiving a mission profile for the candidate mission, the mission profile indicating power demand for the battery during the candidate mission, simulating, by at least one computing device, a remaining energy of the battery based on the mission profile and properties of the battery associated with age and/or previous usage of the battery, and outputting an indication of the fitness of the battery for the candidate mission based, at least in part, on the remaining energy.

### FIELD OF INVENTION

This disclosure relates to techniques for determining a fitness of an energy storage system to accomplish a mission.

### BACKGROUND

Some battery-powered devices, such as electric vehicles, manage their available energy by estimating quantities that are indicative of the current state of their energy storage system (e.g., batteries). Example quantities that are often used in assessing available energy in a battery-powered device include State of Health (SOH), State of Charge (SOC), State of Power (SOP), and State of Temperature (SOT). Because the current state of such quantities is not directly measurable, they are typically estimated.

SOH is typically defined as the capacity of a battery (e.g., in Ampere hours (Ah)) to be able to discharged within the operating voltage range of the battery under steady-state conditions compared to at the beginning of life, expressed as a percentage. As an example, a cell may be continuously discharged at a current of 1 Amps and a temperature of 25° C., until the measured voltage of the battery is equal to the lowest safe voltage (for example, 3.0 V). SOC is typically defined as an amount of power that a battery can currently discharge relative to its full capacity. SOP is typically defined as a rate at which the battery can be discharged. The battery and automotive industries commonly use SOH and the change in resistance to determine when a battery has reached the end of its useful life. Metrics such as SOC, SOH, and SOP may also be used for range estimation (e.g., how far an electric vehicle can be expected to travel without requiring charging).

### SUMMARY

In some embodiments, a computer-implemented method of determining a fitness of a battery for a candidate mission is provided. The method includes receiving a mission profile for the candidate mission, the mission profile indicating power demand for the battery during the candidate mission, simulating, by at least one computing device, a remaining energy of the battery based on the mission profile and properties of the battery associated with age and/or previous usage of the battery, and outputting an indication of the fitness of the battery for the candidate mission based, at least in part, on the remaining energy.

In one aspect, the method further includes measuring a charge and/or resistance associated with the battery, and determining the properties of the battery based, at least in part, on the measured charge and/or resistance. In another aspect, the method further includes measuring an open-circuit voltage associated with the battery, and determining the properties of the battery based, at least in part, on the measured open-circuit voltage. In another aspect, the properties of the battery include capacity loss and/or resistance growth.

In another aspect, the method further includes determining whether a voltage profile associated with the remaining energy of the battery drops below a lowest safe operating range of the battery prior to completion of the mission profile. In another aspect, outputting an indication of the fitness of the battery for the candidate mission comprises outputting, on a user interface, an indication that the candidate mission can be successfully completed when it is determined that the voltage profile associated with the remaining energy of the battery does not drop below a lowest safe operating range of the battery prior to completion of the mission profile. In another aspect, outputting an indication of the fitness of the battery for the candidate mission comprises outputting, on a user interface, and indication that the candidate mission cannot be successfully completed when it is determined that the voltage profile associated with the remaining energy of the battery does drop below a lowest safe operating range of the battery prior to completion of the mission profile.

In another aspect, outputting an indication of the fitness of the battery for the candidate mission based, at least in part, on the remaining energy comprises outputting an indication of a range of an electric vehicle that includes the battery. In another aspect, outputting an indication of the fitness of the battery for the candidate mission based, at least in part, on the remaining energy comprises selecting a route for an electric vehicle that includes the battery.

In some embodiments, a method for determining a fitness of a battery to perform a candidate mission is provided. The method includes receiving a mission profile for the candidate mission, the mission profile indicating power demand for the battery during each of a plurality of steps, determining, using at least one computing device, for each step of the plurality of steps, whether the step can be completed based on available energy of the battery, and outputting an indication of the fitness of the battery to perform the candidate mission based, at least in part, on whether the plurality of steps can be completed.

In one aspect, the available energy of the battery is represented as a region in in N-dimensional space, where Nis greater than one. In another aspect, the region includes dimensions for temperature, voltage, current, and duration. In another aspect, the method further includes receiving measurement data associated with a current and/or resistance of the battery, and updating at least one boundary of the region based on the received measurement data to generate an updated region. In another aspect, outputting an indication of the fitness of the battery to perform the candidate mission comprises outputting an indication that the candidate mission can be completed when it is determined that all of the plurality of steps can be completed. In another aspect, outputting an indication of the fitness of the battery to perform the candidate mission comprises outputting an indication that the candidate mission cannot be completed when it is determined that at least one of the plurality of steps cannot be completed. In another aspect, the region comprises a 4-dimensional region.

In another aspect, outputting a first indication of the fitness of the battery to perform the candidate mission comprises outputting an indication of a range of an electric vehicle that includes the battery. In another aspect, outputting an indication of the fitness of the battery to perform the candidate mission comprises outputting selecting a route for an electric vehicle that includes the battery.

In some embodiments, a system comprising at least one computer processor and at least one computer-readable storage medium having stored thereon instructions is provided. The instructions, when executed, program the at least one computer processor to perform any of the methods described herein.

In some embodiments, at least one computer-readable storage medium is provided. The at least one computer-readable storage medium has stored thereon instructions which, when executed, program at least one processor to perform any of the methods described herein.

### BRIEF DESCRIPTION OF THE DRAWINGS

FIG. 1A schematically illustrates an example energy-intensive mission profile for a battery, in accordance with some embodiments of the present disclosure;

FIG. 1B schematically illustrates an example power-intensive mission profile for a battery, in accordance with some embodiments of the present disclosure;

FIG. 1C is a plot showing a relationship between resistance growth and capacity loss as a battery ages, in accordance with some embodiments of the present disclosure;

FIG. 2A schematically illustrates changes in a voltage profile for batteries having different discharge rates, in accordance with some embodiments of the present disclosure;

FIG. 2B schematically illustrates changes in an energy output for batteries having different discharge rates, in accordance with some embodiments of the present disclosure;

FIG. 3A schematically illustrates voltage discharge profiles for batteries having different resistance and capacity properties when performing an energy-intensive mission profile, in accordance with some embodiments of the present disclosure;

FIG. 3B schematically illustrates voltage discharge profiles for batteries having different resistance and capacity properties when performing a power-intensive mission profile, in accordance with some embodiments of the present disclosure;

FIG. 3C schematically illustrates a mission profile and simulated remaining energy for a battery during performance of the mission profile, in accordance with some embodiments of the present disclosure;

FIG. 4A is a contour plot showing a 2D energy space as a function of applied current and ambient temperature for a new battery, in accordance with some embodiments of the present disclosure;

FIG. 4B is a contour plot showing a 2D energy space as a function of applied current and ambient temperature for an aged battery relative to the battery associated with FIG. 4A, in accordance with some embodiments of the present disclosure;

FIG. 4C is a surface plot showing the difference in energy spaces between a new battery and the aged battery, in accordance with some embodiments of the present disclosure;

FIG. 5 is a flowchart of a process for determining fitness of a battery to perform a mission, in accordance with some embodiments of the present disclosure;

FIG. 6 is a flowchart of a process for determining fitness of a battery to perform a mission using a multi-dimensional region representing the energy space of the battery, in accordance with some embodiments of the present disclosure; and

FIG. 7 schematically illustrates a computing architecture on which some embodiments of the present disclosure may be implemented.

### DETAILED DESCRIPTION

Within an energy storage system (e.g., a battery), a multitude of complex processes happen during charge and discharge cycles of the system based on parameters that change over short (e.g., one charge cycle) and long (e.g., weeks, months, years) periods and based on the loads that are requested from the battery. Properties (e.g., SOH, SOC, SOP, SOT, etc., collectively “SOX”) commonly used to characterize a state of a battery in an electric vehicle or other system (e.g., a robot, a stationary energy storage system) do not take into consideration these complex processes and their effect on whether a particular battery, given its usage history, will be capable of successfully completing a particular mission that has a prescribed power-output profile. However, two batteries with an SOH of 80%, but different usage histories, may not both be able to complete the same mission, depending on the internal state of the batteries and the power demands of the mission. Some embodiments of the present disclosure relate to techniques for determining the “fitness” of an energy storage system to perform a mission that takes into consideration information about the usage and/or current properties of the battery.

Battery cells (also referred to herein as “cells”) have a window within which they are considered safe to operate. This operating range is defined by the manufacturer, and provides the limits within which a battery can be safely used. When a cell is charged to near the highest safe voltage, it is considered “fully charged,” and when the cell is discharged to near the lowest safe voltage, it is considered “fully discharged.”

As cells age, the total usable current that can be extracted while operating within the operating range of the cell decreases. The diminished capacity of the cell over time reduces the usefulness of the battery, and decreases its useability for certain applications. SOH is commonly used to describe this decline in usefulness of a cell.

The inventors have recognized that although SOH is a useful reference point, the decline in a cell's ability to discharge capacity within its operating voltage range can have different limiting factors, which can cause two cells with identical SOH to have different performance capabilities. As described in further detail below, depending on its characteristics, a cell may be considered “capacity-limited” (also known as “energy-limited”) and/or “resistance-limited” (also known as “power-limited”).

For a capacity-limited cell, a primary factor resulting in the decline in dischargeable capacity may be the loss of the materials which store and release electrons within the cell. In a lithium-ion battery (LIB), these materials include lithium and/or the active materials within the electrode of the battery. As the cell is used, these materials are irreversibly lost resulting in a decreased capacity of the cell, which may be captured as a lower SOH. Despite having decreased capacity, such a cell may still be able to provide a large amount of power over a short period of time, but may not be able to provide power over longer periods of time.

For a resistance-limited cell, a primary factor causing the decline in dischargeable capacity may be polarization due to internal resistance of the cell. This polarization may cause the measured voltage of the cell to be lower than before, which may result in the cell reaching the lowest safe voltage of its operating range sooner compared to when the cell was new. Despite having decreased capacity, such a cell may be able to produce a lower amount of current for long periods of time, but may not be able to provide a large amount of power over a short period of time.

In accordance with some embodiments of the present disclosure, a method is provided for determining the “fitness” of a battery for a candidate mission based on usage-informed characteristics of the battery. For example, charge and/or resistance measurements associated with the battery may be used to determine the extent to which the battery can perform a particular candidate mission. For instance, the fitness of the battery may represent the ability of an electric vehicle that includes the battery to complete the candidate mission, the percentage of the distance along the candidate mission that the electric vehicle may travel, etc. In some instances, the fitness of a battery may be conceptualized as a function of applied current, voltage, duration of applied current, and the internal states of the battery at the time of the requested profile.

As used herein, a “mission” is defined as a power output profile (also referred to herein as a “mission profile”) associated with a given task under a given set of conditions. For example, a long mountain climb might have a sustained high power output for several miles at 10° C., while a drive through hilly terrain may be characterized by short periods of high power output, interspersed with recovery periods at 30° C.

The mission profile may have multiple features relevant to the calculation of a battery usage/life for a particular mission, for example the total energy output, the peak power requirements (e.g., a mission profile may have a peak discharge power of 150 kW sustained for 3 seconds, ana peak charge power of 30 kW sustained for 5 seconds), and the operating temperature. Whether the battery is able to perform these features may depend on different aspects of the battery condition, such as the internal resistance, lithium inventory, active material capacity, and open-circuit voltage profiles of the active materials, as well as the vehicle parameters, such as drag and weight. Using knowledge of these parameters, the available energy of the battery within the operating conditions as well as the peak power capabilities can be calculated, which may in turn be used to determine whether the battery will be capable of performing the defined mission.

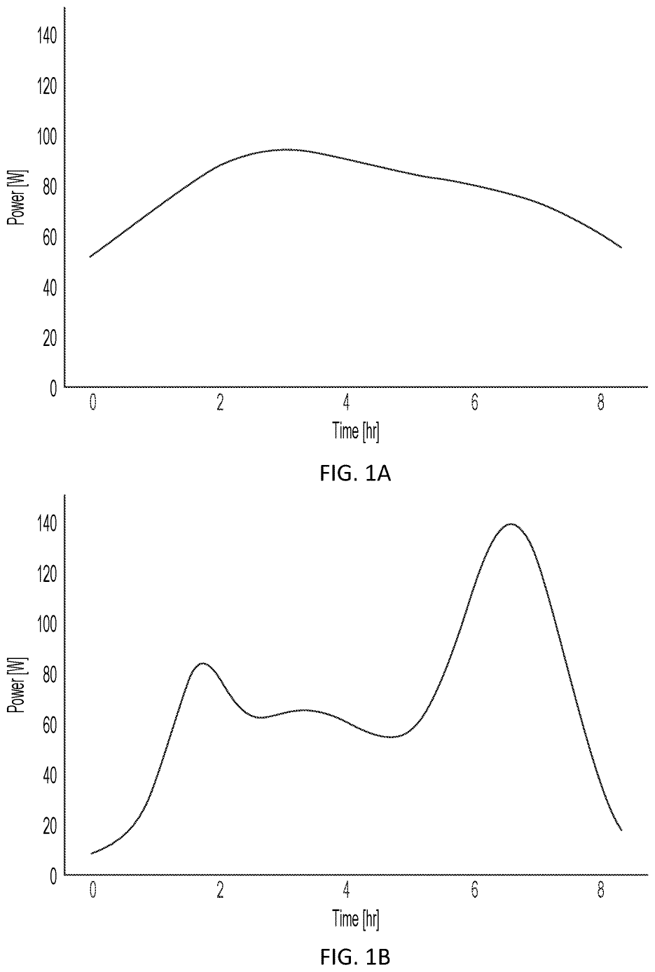

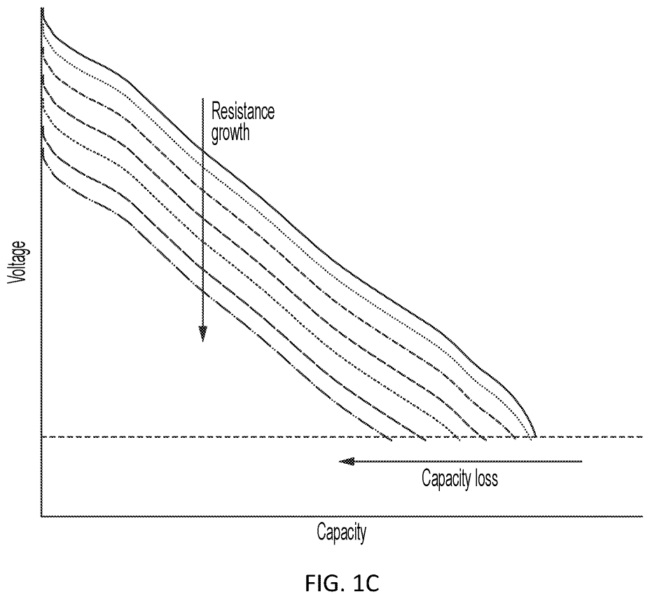

FIG. 1A schematically illustrates an example of an energy-intensive mission profile, in accordance with some embodiments. As can be observed in FIG. 1A, a sustained amount of power is demanded from the battery throughout the mission. FIG. 1B schematically illustrates an example of a power-intensive mission, in accordance with some embodiments. As can be observed in FIG. 1B, the amount of power demanded from the battery varies considerably throughout the mission, with the profile generally showing peaks and valleys of requested power to complete the mission. The area under the curve in FIG. 1A may be greater than that in FIG. 1B, even though the peak power in FIG. 1A may be lower than that in FIG. 1B.

In accordance with some embodiments, a method is provided for determining a state of health/state of charge of a battery at a given time in a way that departs from conventional techniques, which rely on reaching a pre-defined minimum voltage (e.g., the lowest voltage of the battery's operating range). Such techniques may allow for deeper discharge of the battery (e.g., for a particular type of mission), and a better quantification of the energy available from the battery.

The inventors have recognized and appreciated that some current-based techniques for determining fitness of a battery may be misleading as they do not take into consideration variable resistance and voltages of the battery. In accordance with some embodiments, a method is provided for determining the fitness of a battery as a multi-dimensional quantity related to temperature and mission, which may be power and time based rather than current based.

In accordance with some embodiments, a system is provided, comprising at least one computer processor and at least one computer-readable storage medium having stored thereon instructions which, when executed, program the at least one computer processor to perform any of the methods described herein.

In accordance with some embodiments, at least one computer-readable storage medium is provided, having stored thereon instructions which, when executed, program at least one processor to perform any of the methods described herein.

The inventors have recognized and appreciated that some conventional techniques for determining how a battery cell has aged are inaccurate. Some embodiments of the present disclosure relate to a method of determining the power that a cell may be capable of delivering for performance of a candidate mission, taking into consideration the power demands of the mission profile, and a usage-informed view of the battery characteristics.

As described above, SOH is a measure of a battery's capacity, or the number of electrons that can be passed between the electrodes of the battery during a discharge step under a pre-determined set of conditions. However, accelerating a vehicle is a task that requires energy over a period of time, hence it may be advantageous to consider power (the product of voltage and current) when assessing the SOH of a battery. For example: A 10 amp current at 2.5 volts corresponds to a power of 25 watts. A vehicle might demand 25 watts from the cell for a period of 1 hour to complete a mission, so the energy needed for the mission is 25 watt-hours. However, resistance growth associated with a particular cell may drive its output voltage down to 2.2 volts. In such a case, the cell can only produce 22 watts for the 1 hour mission profile (assuming it is able to maintain the voltage and current over that time) so the battery is now rated to only 22 watt-hours. In practice, the battery may be incapable of maintaining the voltage and/or current over the entire 1 hour period of time if the battery has significant degradation. Accordingly, determining the total power that can be produced by the cell over the 1 hour time period for a mission may more accurately represent the current state of health and capacity for generation of power from the cell (e.g., with regard to completing the mission).

The open-circuit voltage (OCV) describes the equilibrium potential of an electrode, or the difference between electrodes, expressed over a range of lithiation states. In some embodiments, based on an understanding of the OCV of a cell, the remaining amount of active material in a battery to be discharged can be determined without resistive losses. As a result of an applied current to the battery, the corresponding overpotential and voltage drop can be added, and a relationship between losing capacity and resistance buildup can be provided. A schematic showing such a relationship between resistance growth and capacity loss is shown in FIG. 1C.

In some embodiments, knowledge about the current state of the battery impacted by its usage and/or age may be used to determine the fitness of the battery. As described herein, the voltage profile of a battery is context-dependent. Two identical batteries discharged to the same voltage at different rates (i.e., different usages) will pass different amounts of energy, despite both batteries being “fully discharged,” according to a conventional cutoff voltage definition. Therefore, a standard SOH calculation will determine that the battery discharged at a higher rate has a lower SOH than the battery discharged at a lower rate, despite starting from identical conditions. To determine the lithiation capability of the battery, the resting voltage can be compared to the known OCV of the battery to obtain an estimate of the fitness of the battery.

An example of this process is as follows: given prior knowledge of a battery system, the OCV, or voltage at any given lithiation state, may be determined. When a battery is at rest, the battery is at equilibrium, and therefore the lithiation state of the battery may also be determined. By comparing the equilibrium voltage of the battery at the beginning and end of a discharge step, the actual change in SOC can be calculated. The maximum discharge capacity for that battery may be determined by comparing the actual change in SOC to the capacity discharged during the discharge step. For example, if 0.5 Ah of capacity is discharged, resulting in a calculated SOC change of 10%, then the battery may be considered to have a maximum discharge capacity of 5 Ah. If the same value at the beginning of life was 6 Ah, the battery may have 83% SOH, or OCV-informed State-Of-Health (OSOH), which is the SOH calculated using the resting voltage of the battery compared to a previously determined OCV of the battery. A similar calculation can be made for an OCV-informed State-of-Charge (OSOC) of a battery, which is the SOC calculated using the resting voltage of the battery compared to a previously-determined OCV of the battery.

Some embodiments of the present disclosure relate to the use of battery knowledge to quantify the operating parameters of the battery. As discussed herein, most batteries have a characteristic operating voltage range that the manufacturer has determined is safe for long-term usage. This tends to be related to three main concerns:
At extreme levels of lithiation, the active materials, particularly in the cathode, are unstable. As an example, lithium cobalt oxide (LCO), is well-known to become unstable at lithium levels less than 50% of the starting amount.
At high states of charge, the potential of the anode approaches 0 V relative to Li/Li⁺. This increases the risk of negative events such as lithium plating and dendrite formation
At extreme potentials, electrolyte reactivity is increased

These three concerns are all related to the potential of the electrode material itself, or to the level of lithiation of the electrode. However, as described above, the voltage profile of a battery is context-dependent. The overall potential of a battery in operation includes contribution from resistance-based overpotentials, along with the actual potential difference between the two electrodes. That potential difference is not taken into consideration when setting the manufacturer-specified operating voltage range for the battery. The inventors have recognized that considering information about usage-imposed limitations of a battery (e.g., resistance buildup, capacity loss) may be useful for accurately determining the safe long-term operating range of a battery, which may differ from the manufacturer-specified operating range.

In some embodiments, knowledge of the battery OCV is used to calculate the true potential of the electrodes at any given point in time, thus enabling the determination of a degradation, battery calendar age, and mission profile-informed instantaneous safe power limit to enable a full discharge of the battery without exceeding the safe operating voltage range of the battery.

An example of such a calculation is as follows: OSOH indicates that 10% of the battery's lithium ions could be discharged if resistive losses were omitted from consideration. Changes in battery resistance over time mean that a 65 kW load would cause the battery voltage to reach its lower voltage safety cutoff at the battery's current temperature and SOC. If the vehicle enforces a power limit greater than 65 kW, that would no longer be appropriate for the battery and thus would need to be reduced. Alternatively, if the vehicle enforces a power limit less than 65 kW, the power limit could theoretically be increased accordingly.

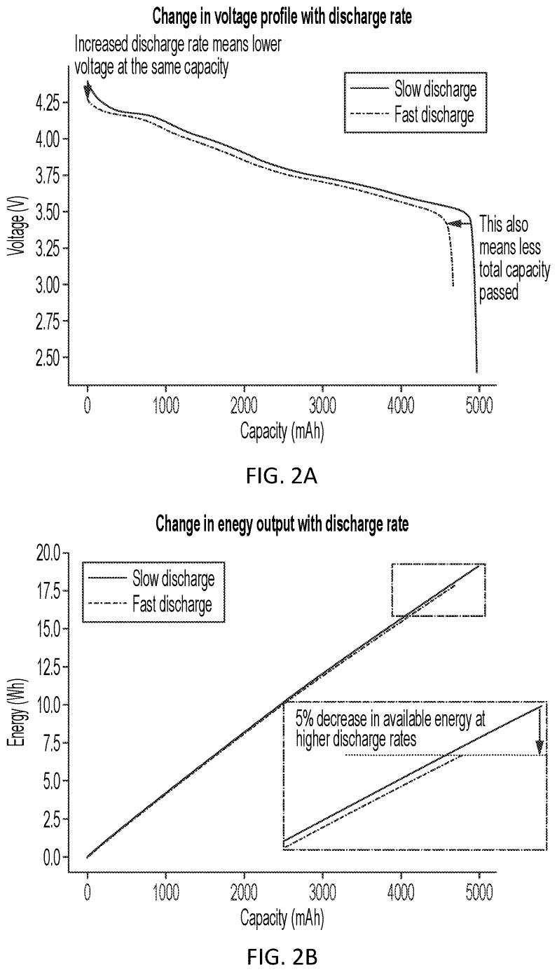

FIGS. 2A and 2B schematically illustrate how discharge rate, or alternately increasing resistance of a cell may impact the voltage and available energy (e.g., capacity) of the cell. By increasing the current (or increasing the resistance), the nth electron passed from the battery will do so at a lower voltage difference, thus decreasing the total available energy in the battery. In the example of FIGS. 2A and 2B, two illustrative discharge rates (slow discharge and fast discharge) are shown. It should be appreciated, however, that discharge rates vary along a continuum based on power demanded from a battery to perform a particular mission. As is evident in the simplistic example shown in FIG. 2B, even if the same number of electrons are passed in the slow discharge condition compared to the fast discharge condition, the energy transferred will be less in the slow discharge scenario, thereby increasing the available energy of the battery and improving the ability of the battery to perform the mission.

As described herein, whether a particular battery is likely to be able to complete a mission having a particular mission profile may be dependent on usage-informed characteristics of the battery such as resistance and capacity. As an example, consider a high-resistance, high capacity cell, an associated high power candidate mission profile, and how performance of the candidate mission may affect future performance of the cell:
The cell may be less efficient for power delivery by a certain amount due to the high resistance of the cell. Additionally, performing the mission at lower sustained states of charge (SOCs) may result in a higher risk of the cell falling below the lowest safe operation voltage for the cell.
The higher power demand associated with the mission profile (or temperature, pressure, etc.) may accelerate the resistance buildup within the cell by a certain amount. If operating conditions are met, there may be a higher risk of catastrophic material failure within the battery pack due to the accelerated resistance buildup.

In this way, it can be determined that if a vehicle including the high-resistance, high capacity cell performs the mission, the result may be a lower range for the vehicle and/or with increased damage (e.g., accelerated resistance growth). Additionally, the accelerated resistance growth may, under certain operating conditions, result in the trigger of a safety shutoff and/or catastrophic failure of the cell.

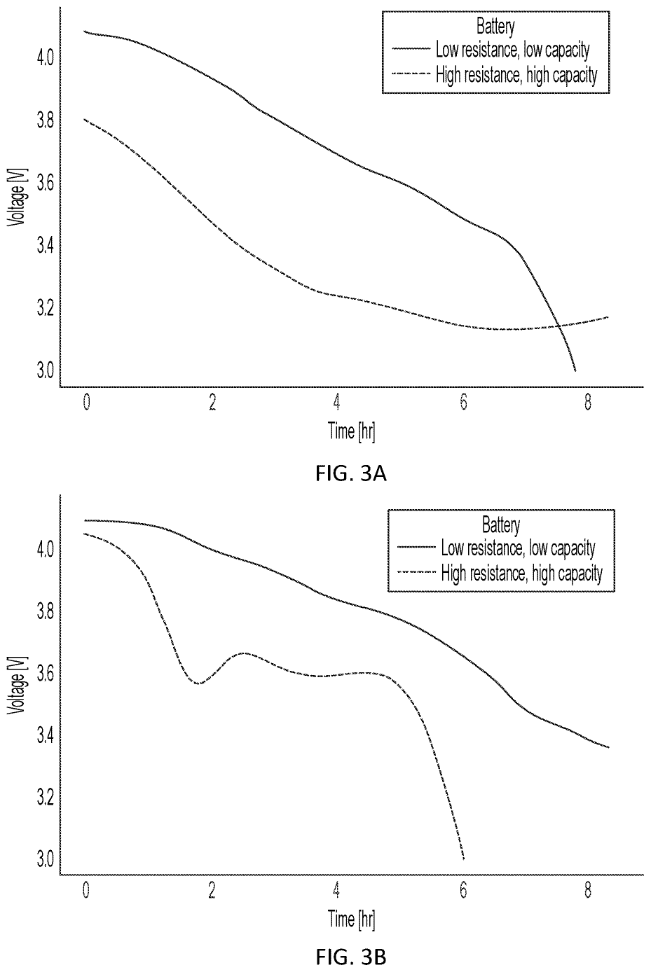

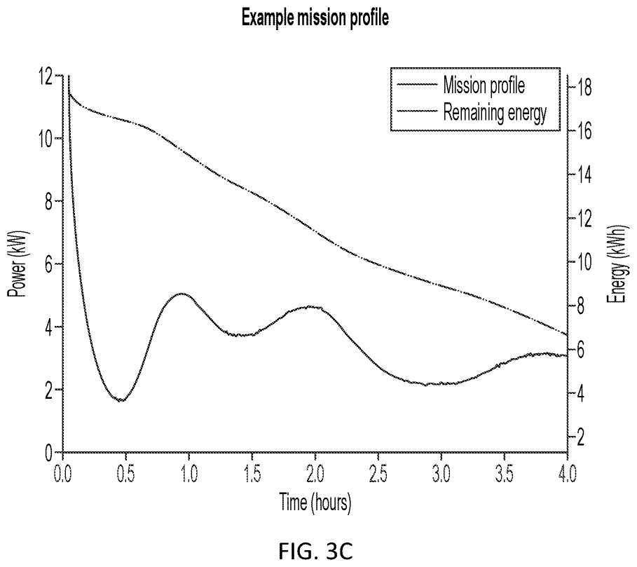

FIGS. 3A and 3B illustrate simulated voltage responses of batteries with different properties (e.g., resistance, capacity) attempting to perform an example energy-intensive profile (FIG. 3A) and an example power-intensive profile (FIG. 3B). Although FIGS. 3A and 3B only illustrate batteries having two (e.g., low or high) resistance and capacity properties, it should be appreciated that resistance and capacity characteristics of a battery may exist along a continuum and the simulation example shown in FIGS. 3A and 3B is provided merely for illustration purposes.

FIG. 3A shows simulation results for a first battery having low resistance and low capacity and a second battery having high resistance and high capacity performing the same energy-intensive profile (e.g., the energy-intensive profile shown in FIG. 1A). In FIG. 3A the voltage responses of the respective batteries over the course of the mission profile are illustrated. As can be observed, the first battery (low resistance, low capacity) is unable to complete the energy-intensive mission due to voltage response falling below the lowest safe operating voltage of the battery, whereas the second battery (high resistance, high capacity) is able to complete the energy-intensive mission.

FIG. 3B shows simulation results for a first battery having low resistance and low capacity and a second battery having high resistance and high capacity performing the same power-intensive profile (e.g., the power-intensive profile shown in FIG. 1B). In FIG. 3B the voltage responses of the respective batteries over the course of the mission profile are illustrated. As can be observed, the second battery (high resistance, high capacity) is unable to complete the power-intensive mission due to voltage response falling below the lowest safe operating voltage of the battery, whereas the first battery (low resistance, low capacity) is able to complete the energy-intensive mission.

In the example shown in FIGS. 3A and 3B, the first and second batteries may have a similar (or the same) SOH (e.g., 80% SOH) when calculated using conventional techniques. However, the ability of the batteries to perform specific types of missions varies considerably based on the type of properties (e.g., resistance, capacity) that are not taken into consideration in conventional techniques. In this way, the first battery may be suitable for use in some mission profiles, but not suitable for use in other mission profiles. Conversely, the second battery may be suitable for use in some mission profiles that the first battery is not suitable to perform, but not suitable for use in some mission profiles that the first battery is suitable to perform.

FIG. 3C schematically illustrates a mission profile and a simulated energy amount shown on the same graph with different vertical axes.

Simulating the energy of a battery over the course of a mission profile may be performed in any suitable way. In one example, measurements of the battery may be made and analyzed to understand one or more aspects of the internal state of the battery (e.g., resistance buildup), which can be used in the simulation.

An example of how to calculate the available energy for a battery in accordance with some embodiments of the present disclosure is as follows: the OCV of a battery describes the equilibrium potential of the battery as a function of the capacity discharged. The operating voltage profile of the battery may be derived from the OCV, depending on the usage conditions and age of the battery. For example, a battery with an internal resistance of 20 mOhms subjected to a constant current of 1 Amp will have a voltage profile that is shifted by (20 mOhms*1 Amp=20 mV). Considering the operating voltage profile across a set of operating conditions may lead to an overall energy output of the battery during the mission (examples of which are shown in FIGS. 3A and 3B). The peak power output by the battery may be determined as the maximum current the battery can sustain multiplied by the maximum operating voltage. As described in further detail below, the simulated energy output during a mission profile may be used to determine whether a particular battery is capable of performing the mission profile (e.g., determining mission fitness), may be used to estimate the range of a vehicle including the battery, and/or may be used to provide a more accurate estimate of the health of the battery or the like.

As more data is obtained about the battery, the energy profile determination can increase in complexity. For example, rather than using a single value for battery resistance, a profile of resistances over the state of charge (SOC) range can be used to obtain a more accurate measurement of energy and peak power. In some embodiments, current may be used in the energy estimation calculation, as the mission profile may specify a varying power output rather than a constant current output. The available energy and peak power under the mission conditions may also be obtained through a full physics-based simulation. Though a full physics-based simulation may not be required to extract the available energy and peak power of a battery, using such a simulation methodology may facilitate extraction of supplemental parameters on the internal states of the cell which could aid in extracting the available energy and peak power of the cell.

The inventors have recognized and appreciated that determining the fitness of a battery to perform a particular mission is a function of multiple quantities (e.g., temperature, mission profile conditions, duration of any applied current, age of the battery, etc.). In some embodiments, an energy space may be defined as a region in N-dimensional space (e.g., 4D space, where N=4)) that describes the boundaries of one or more battery cells to produce current at a voltage for a period of time at a given temperature. The energy space may represent the set of all possible missions that can be successfully performed by tracing a path through the region in N-dimensional space based on the parameters of the mission profile (e.g., temperature, voltage, current, duration, etc.). For example, a mission may take place at a defined temperature profile. When N=4, the mission may be extracted as a volume within the region in N-dimensional space. The surface at a given temperature slice may represent the energy (current*voltage*duration) for the mission.

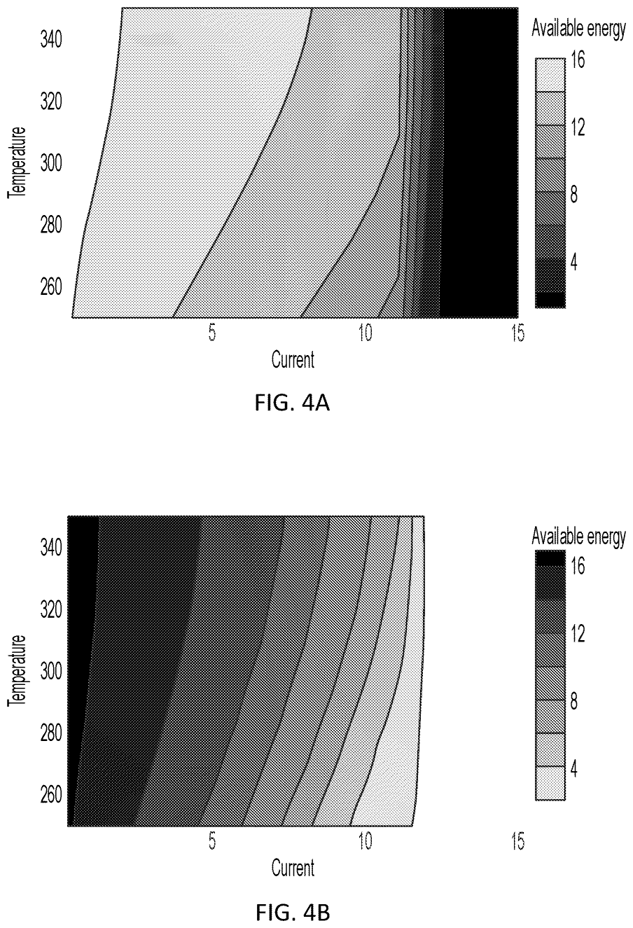

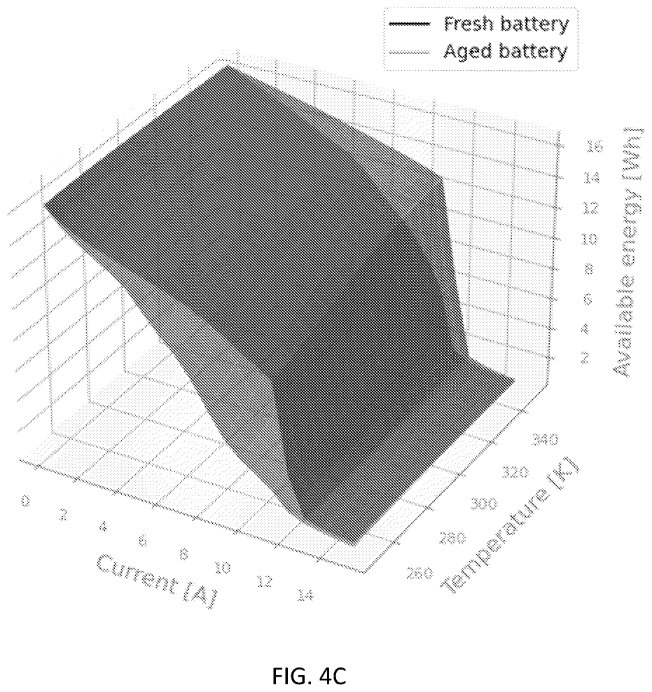

FIG. 4A is a contour plot showing a 2D energy space (e.g., a region in N-dimensional space, with N=2) as a function of applied current and ambient temperature for a battery. FIG. 4B is a contour plot showing a 2D energy space (e.g., a region in N-dimensional space, with N=2) as a function of applied current and ambient temperature for the battery associated with FIG. 4A after aging. FIG. 4C is a surface plot that compares the energy space for a new battery (e.g., the battery associated with FIG. 4A) with the energy space for an aged battery (e.g., the battery associated with FIG. 4B). As shown in FIG. 4C, as a battery ages, the energy space may shrink at its boundaries, such that the battery is no longer able to perform some missions that it may have been able to perform previously. The total volume of the energy space at start compared to a zero volume space (e.g., the ultimate end) or a specific mission-defined volume may be considered as the “zero-percent” state. The effective age of the battery (e.g., as a percentage) may be determined as a function of the change in the volume of the energy space. Because the internal processes of the battery throughout its lifetime are complex and based on its particular usage, the function describing the change in the volume of the energy may also be complex and may be non-linear.

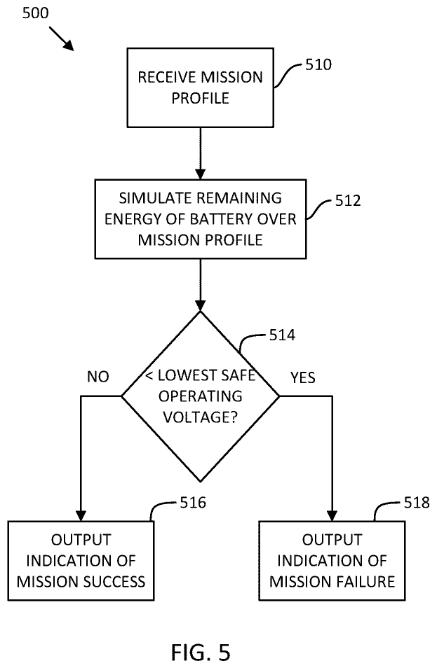

FIG. 5 is a flowchart of a process 500 for determining a fitness of a battery to perform a mission in accordance with some embodiments of the present disclosure. Process 500 begins in act 510, where a mission profile is received. For instance, the mission profile may be received in response to a user input. The user input may specify a route from a first location to a second location (e.g., input into a navigation system of an electric vehicle), and the mission profile may be determined based on information about the route, the driving history of the driver, traffic associated with the route, temperature during the mission, or any other suitable information pertaining to the mission. Process 500 then proceeds to act 512, where the remaining energy of a battery over the mission profile is determined using a simulation that takes into account information about the current state (e.g., resistance, capacity) of the battery. For example, an OCV of the battery may be measured and the remaining energy of the battery during the mission profile may be determined based, at least in part, on the measured OCV. In some embodiments, more complex information indicating a current lithiation state of the battery, resistance growth, or other battery properties may be measured and/or estimated based on how the battery has been used. Such information may be used to simulate the remaining energy of the battery over the mission profile.

Process 500 may then proceed to act 514, where it is determined whether the voltage profile of the simulated remaining energy drops below the lowest safe operating voltage of the battery prior to the end of the mission defined by the mission profile. If it is determined in act 514 that the voltage profile does not drop below the lowest safe operating voltage, process 500 proceeds to act 516, where an indication that the mission can be successfully completed is output. Otherwise, if it is determined in act 514 that the voltage profile does drop below the lowest safe operating voltage, process 500 proceeds to act 518, where an indication that the mission cannot be successfully completed is output.

Although the exemplary process 500 is shown as outputting a binary response (e.g., whether the mission can be successfully completed), it should be appreciated that other indications can alternatively be output. For example, the systems described herein may be configured to output a range that a vehicle incorporating the battery can safely travel according to the mission profile. In some embodiments, the systems described herein may be configured to recommend a travel route between two locations that aligns with simulated energy available. For instance, several routes between city A and city B may exist, and some embodiments, may determine, which of the several routes to recommend to an operator of the vehicle based, at least in part, on a mission profile associated with each of the routes and the simulated energy available. In some embodiments, the recommendation of a particular route may be informed based on whether performance of the mission along the route is likely to cause less long-term damage to the battery compared with other possible routes.

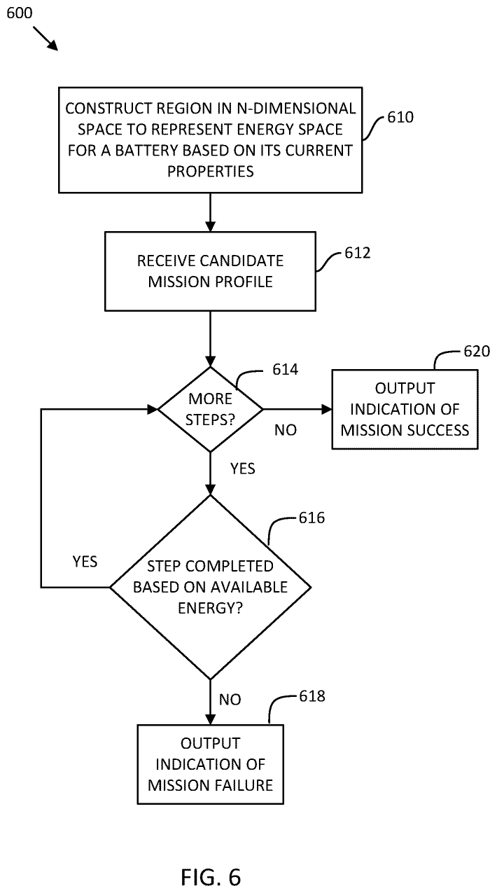

FIG. 6 is a flowchart of a process 600 for determining a fitness of a battery to perform a mission in accordance with some embodiments of the present disclosure. Process 600 begins in act 610, where a region in N-dimensional space is constructed to represent an energy space for a battery based on its current state (e.g., characterized using SOC, energy level, OCV, etc.) through usage and/or age of the battery. The region in N-dimensional space may describe the available energy that can be output from the battery as a function of current, temperature, voltage, etc. As described above, the energy space may be dynamically updated as the battery continues to age and/or is used. For example, as the battery ages it may no longer be able to perform some processes that require fast discharging, fast charging, performance in low temperatures, etc., and this may reflected as a shrinking energy space over time. Process 600 then proceeds to act 612, where a candidate mission profile is received. The candidate mission profile may be received in any suitable way, examples of which are described in connection with process 500 in FIG. 5.

The candidate mission profile may include a plurality of steps through time to complete the mission profile. Each step may carries forward the battery state X (e.g., characterized by one of SOC, energy level, OCV, etc.) from the previous step in the mission profile. After receiving the mission profile in act 612, process 600 may proceed to act 614, where it is determined whether additional steps in the mission profile are to be completed. If it is determined that there are additional steps, process 600 proceeds to act 616, where it is determined whether the current step can be completed based on the available energy of the battery. At each step, the region in N-dimensional space may be a function f=F(X). The function f maps (x0, x1, . . . ) to available energy of the battery (e.g., determined based on simulation as described herein), where x0, x1, . . . denote current, temperature, etc. Accordingly, if it is determined that the current step cannot be completed because there is insufficient energy, process 600 proceeds to act 618, where an indication that the mission cannot be successfully completed may be output. If it is determined in act 616 that the current step can be completed, process 600 returns to act 614 to determine whether there are any additional steps in the mission profile. If it is determined that there are no additional steps, process 600 may proceed to act 616, where an indication that the process may be successfully completed is output.

It should be appreciated that variations on process 600 are also contemplated. For instance, rather than receiving a particular mission in act 612 and determining whether the received mission can be successfully completed based on the current properties of the battery, in some embodiments, a plurality of possible missions based on the current properties of the battery may be presented in a user interface to a user of the vehicle that includes the battery. In some embodiments, a recommendation of a route that may be completed may be provided to the user via the user interface.

In some embodiments, current properties of a plurality of batteries for a fleet of electric vehicles may be modeled in accordance with one or more the techniques described herein, and a particular vehicle may be selected based on a particular mission that is to be performed. For instance, an electric vehicle having a battery with high resistance and high capacity may be selected for an energy intensive mission profile, whereas an electric vehicle having a battery with low resistance and low capacity may be selected for a power-intensive mission profile.

In some embodiments, the current properties of a battery may be used to select a second usage for a battery. For instance, a battery that has reached 80% SOH may no longer be suitable for use in an electric vehicle. Knowledge on various properties of the battery (e.g., resistance, capacity) may be useful in deciding how the battery can be reused after removal from the electric vehicle. For example, the battery may work well for certain tasks and may not be fit for other tasks. In this way, used batteries can be repurposed more intelligently based on their current properties and available energy to perform various tasks, rather than merely being put into a stationary storage facility.

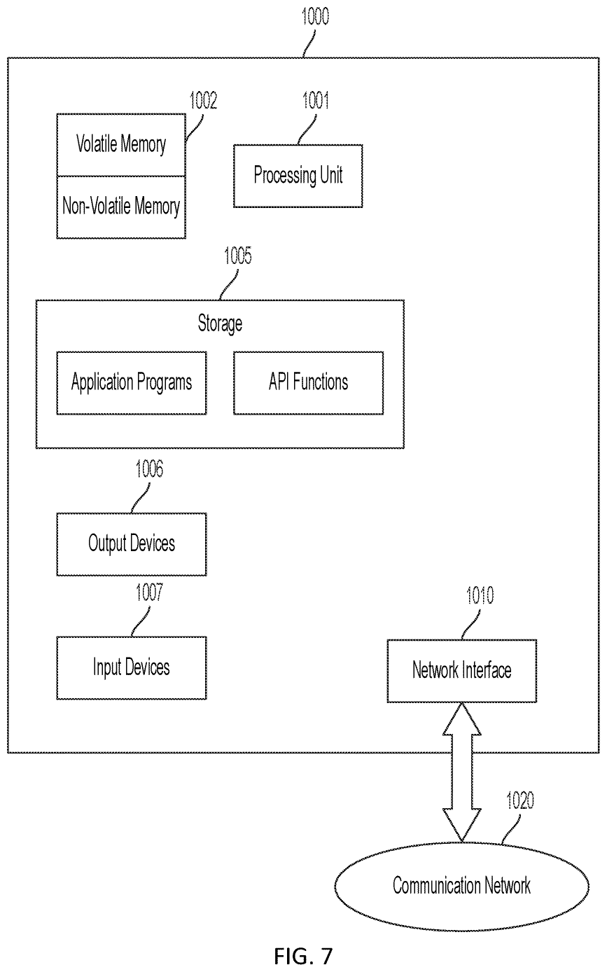

FIG. 7 shows, schematically, an illustrative computer 1000 on which any aspect of the present disclosure may be implemented.

In the example of FIG. 7, the computer 1000 includes a processing unit 1001 having one or more computer hardware processors and one or more articles of manufacture comprising at least one non-transitory computer-readable medium (e.g., a memory 1002 that may include, for example, volatile and/or non-volatile memory). The memory 1002 may store one or more instructions to program the processing unit 1001 to perform any of the functionalities described herein. The computer 1000 may also include other types of non-transitory computer-readable media, such as a storage 1005 (e.g., one or more disk drives) in addition to the memory 1002. The storage 1005 may also store one or more application programs and/or resources used by application programs (e.g., software libraries), which may be loaded into the memory 1002. Thus, the memory 1002 and/or the storage 1005 may serve as one or more non-transitory computer-readable media storing instructions for execution by the processing unit 1001.

The computer 1000 may have one or more input devices and/or output devices, such as devices 1006 and 1007 illustrated in FIG. 7. These devices may be used, for instance, to present a user interface. Examples of output devices that may be used to provide a user interface include printers, display screens, and other devices for visual output, speakers and other devices for audible output, braille displays and other devices for haptic output, etc. Examples of input devices that may be used for a user interface include keyboards, pointing devices (e.g., mice, touch pads, and digitizing tablets), microphones, etc. For instance, the input devices 1007 may include a microphone for capturing audio signals, and the output devices 1006 may include a display screen for visually rendering, and/or a speaker for audibly rendering, recognized text.

In the example of FIG. 7, the computer 1000 also includes one or more network interfaces (e.g., a network interface 1010) to enable communication via various networks (e.g., a network 1020). Examples of networks include local area networks (e.g., an enterprise network), wide area networks (e.g., the Internet), etc. Such networks may be based on any suitable technology operating according to any suitable protocol, and may include wireless networks and/or wired networks (e.g., fiber optic networks).

Having thus described several aspects of at least one embodiment, it is to be appreciated that various alterations, modifications, and improvements will readily occur to those skilled in the art. Such alterations, modifications, and improvements are intended to be within the spirit and scope of the present disclosure. Accordingly, the foregoing descriptions and drawings are by way of example only.

The above-described embodiments of the present disclosure can be implemented in any of numerous ways. For example, the embodiments may be implemented using hardware, software, or a combination thereof. When implemented in software, the software code may be executed on any suitable processor or collection of processors, whether provided in a single computer, or distributed among multiple computers.

Also, the various methods or processes outlined herein may be coded as software that is executable on one or more processors running any one of a variety of operating systems or platforms. Such software may be written using any of a number of suitable programming languages and/or programming tools, including scripting languages and/or scripting tools. In some instances, such software may be compiled as executable machine language code or intermediate code that is executed on a framework or virtual machine. Additionally, or alternatively, such software may be interpreted.

The techniques described herein may be embodied as a non-transitory computer-readable medium (or multiple such computer-readable media) (e.g., a computer memory, one or more floppy discs, compact discs, optical discs, magnetic tapes, flash memories, circuit configurations in Field Programmable Gate Arrays or other semiconductor devices, or other non-transitory, tangible computer-readable medium) encoded with one or more programs that, when executed on one or more processors, perform methods that implement the various embodiments of the present disclosure described above. The computer-readable medium or media may be portable, such that the program or programs stored thereon may be loaded onto one or more different computers or other processors to implement various aspects of the present disclosure as described above.

The terms “program” or “software” are used herein to refer to any type of computer code or set of computer-executable instructions that may be employed to program one or more processors to implement various aspects of the present disclosure as described above. Moreover, it should be appreciated that according to one aspect of this embodiment, one or more computer programs that, when executed, perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Program modules may include routines, programs, objects, components, data structures, etc. that perform particular tasks or implement particular abstract data types. Functionalities of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields to locations in a computer-readable medium, so that the locations convey how the fields are related. However, any suitable mechanism may be used to relate information in fields of a data structure, including through the use of pointers, tags, and/or other mechanisms that establish how the data elements are related.

Various features and aspects of the present disclosure may be used alone, in any combination of two or more, or in a variety of arrangements not specifically described in the foregoing, and are therefore not limited to the details and arrangement of components set forth in the foregoing description or illustrated in the drawings. For example, aspects described in one embodiment may be combined in any manner with aspects described in other embodiments.

Also, the techniques described herein may be embodied as methods, of which examples have been provided. The acts performed as part of a method may be ordered in any suitable way. Accordingly, embodiments may be constructed in which acts are performed in an order different from illustrated, which may include performing some acts simultaneously, even though shown as sequential acts in illustrative embodiments.

Use of ordinal terms such as “first,” “second,” “third,” etc. in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

Also, the phraseology and terminology used herein is for the purpose of description and should not be regarded as limiting. The use of “including,” “comprising,” “having,” “containing,” “involving,” “based on,” “according to,” “encoding,” and variations thereof herein, is meant to encompass the items listed thereafter and equivalents thereof as well as additional items.

1. A computer-implemented method of determining a fitness of a battery for a candidate mission, the method comprising:
receiving a mission profile for the candidate mission, the mission profile indicating power demand for the battery during the candidate mission;
simulating, by at least one computing device, a remaining energy of the battery based on the mission profile and properties of the battery associated with age and/or previous usage of the battery; and
outputting an indication of the fitness of the battery for the candidate mission based, at least in part, on the remaining energy.

2. The method of claim 1, further comprising:
measuring a charge and/or resistance associated with the battery; and
determining the properties of the battery based, at least in part, on the measured charge and/or resistance.

3. The method of claim 1, further comprising:
measuring an open-circuit voltage associated with the battery; and
determining the properties of the battery based, at least in part, on the measured open-circuit voltage.

4. The method of claim 1, wherein the properties of the battery include capacity loss and/or resistance growth.

5. The method of claim 1, further comprising:
determining whether a voltage profile associated with the remaining energy of the battery drops below a lowest safe operating range of the battery prior to completion of the mission profile.

6. The method of claim 5, wherein outputting an indication of the fitness of the battery for the candidate mission comprises outputting, on a user interface, an indication that the candidate mission can be successfully completed when it is determined that the voltage profile associated with the remaining energy of the battery does not drop below a lowest safe operating range of the battery prior to completion of the mission profile.

7. The method of claim 5, wherein outputting an indication of the fitness of the battery for the candidate mission comprises outputting, on a user interface, and indication that the candidate mission cannot be successfully completed when it is determined that the voltage profile associated with the remaining energy of the battery does drop below a lowest safe operating range of the battery prior to completion of the mission profile.

8. The method of claim 1, wherein outputting an indication of the fitness of the battery for the candidate mission based, at least in part, on the remaining energy comprises outputting an indication of a range of an electric vehicle that includes the battery.

9. The method of claim 1, wherein outputting an indication of the fitness of the battery for the candidate mission based, at least in part, on the remaining energy comprises selecting a route for an electric vehicle that includes the battery.

10. A method for determining a fitness of a battery to perform a candidate mission, the method comprising:
receiving a mission profile for the candidate mission, the mission profile indicating power demand for the battery during each of a plurality of steps;
determining, using at least one computing device, for each step of the plurality of steps, whether the step can be completed based on available energy of the battery; and
outputting an indication of the fitness of the battery to perform the candidate mission based, at least in part, on whether the plurality of steps can be completed.

11. The method of claim 10, wherein the available energy of the battery is represented as a region in in N-dimensional space, where Nis greater than one.

12. The method of claim 11, wherein the region includes dimensions for temperature, voltage, current, and duration.

13. The method of claim 11, further comprising:
receiving measurement data associated with a current and/or resistance of the battery; and
updating at least one boundary of the region based on the received measurement data to generate an updated region.

14. The method of claim 13, wherein outputting an indication of the fitness of the battery to perform the candidate mission comprises outputting an indication that the candidate mission can be completed when it is determined that all of the plurality of steps can be completed.

15. The method of claim 14, wherein outputting an indication of the fitness of the battery to perform the candidate mission comprises outputting an indication that the candidate mission cannot be completed when it is determined that at least one of the plurality of steps cannot be completed.

16. The method of claim 11, wherein the region comprises a 4-dimensional region.

17. The method of claim 10, wherein outputting a first indication of the fitness of the battery to perform the candidate mission comprises outputting an indication of a range of an electric vehicle that includes the battery.

18. The method of claim 10, wherein outputting an indication of the fitness of the battery to perform the candidate mission comprises outputting selecting a route for an electric vehicle that includes the battery.

19. A system comprising at least one computer processor and at least one computer-readable storage medium having stored thereon instructions which, when executed, program the at least one computer processor to perform the method of any of claims 1-18.

20. At least one computer-readable storage medium is provided, having stored thereon instructions which, when executed, program at least one processor to perform the method of any of claims 1-18.
